(19) United States
(12) Patent Application Publication
(10) Pub. No.: US 2025/0287649 A1
(43) Pub. Date: Sep. 11, 2025

(54) INTEGRATED CIRCUIT SEMICONDUCTOR DEVICES AND METHODS OF FORMING SAME

(71) Applicant: SAMSUNG ELECTRONICS CO., LTD., Suwon-si (KR)

(72) Inventors: Jin-Seong Park, Seoul (KR); Teawon Kim, Suwon-si (KR); Jihyun Kho, Suwon-si (KR); Dong-Gyu Kim, Seoul (KR); Yurim Kim, Suwon-si (KR); Seunghee Lee, Suwon-si (KR); Seungwoo Jang, Suwon-si (KR); Tae Woong Cho, Seoul (KR); Yong-Suk Tak, Suwon-si (KR)

(73) Assignees: SAMSUNG ELECTRONICS CO., LTD., Suwon-si (KR); IUCF-HYU (Industry-University Cooperation Foundation Hanyang University), Seoul (KR)

(21) Appl. No.: 18/916,794

(22) Filed: Oct. 16, 2024

(30) Foreign Application Priority Data
Mar. 6, 2024 (KR) 10-2024-0032148
May 20, 2024 (KR) 10-2024-0065351

(51) Int. Cl. H01L 29/786; H01L 29/04; H01L 29/32; H10B 12/00

(52) U.S. Cl. CPC H10D 30/6755; H10B 12/34; H10B 12/482; H10B 12/488; H10D 62/40; H10D 62/53

(57) ABSTRACT

A semiconductor device includes a buffer pattern having a conductive pattern thereon; the buffer pattern includes at least one of hafnium oxide, zirconium oxide, and aluminum oxide. An oxide semiconductor pattern is provided, which extends between the buffer pattern and the conductive pattern; the oxide semiconductor pattern has a mean grain size in a range from 10 nm to 17 nm.

### REFERENCE TO PRIORITY APPLICATION

This U.S. non-provisional patent application claims priority under 35 U.S.C. § 119 to Korean Patent Application No. 10-2024-0032148, filed Mar. 6, 2024, and Korean Patent Application No. 10-2024-0065351, filed May 20, 2024, the disclosures of which are hereby incorporated herein by reference.

### BACKGROUND

The inventive concept relates to integrated circuit semiconductor and memory devices, and methods of manufacturing the same.

Due to their small-sized, multifunctional and/or low-cost characteristics, semiconductor devices are widely used in the electronics industry. These semiconductor devices may be classified into memory devices for storing logic data, logic devices for processing the logic data, and hybrid devices including both memory and logic elements.

As demand for high speed and low power consumption electronic devices increases, semiconductor devices with high operating speeds and/or low operating voltages are being developed with high integration density. However, as the integration density of the semiconductor devices increases, electrical characteristics and production yield of the semiconductor devices may deteriorate. Accordingly, many studies are being conducted to improve the electrical characteristics and production yield of semiconductor devices.

### SUMMARY

An object of the inventive concept is to provide semiconductor devices with improved electrical characteristics and reliability, and methods of manufacturing the same.

A semiconductor device according to some embodiments of the inventive concept may include a buffer pattern, a conductive pattern on the buffer pattern, and an oxide semiconductor pattern between the buffer pattern and the conductive pattern. In some embodiments, the buffer pattern may include at least one of hafnium oxide, zirconium oxide, and aluminum oxide, and a mean grain size of the oxide semiconductor pattern may be in a range from 10 nm to 17 nm.

A semiconductor device according to some embodiments of the inventive concept may include a buffer pattern, an oxide semiconductor pattern on the buffer pattern, and a conductive pattern on the oxide semiconductor pattern. According to some embodiments, the buffer pattern may include at least one of hafnium oxide, zirconium oxide, and aluminum oxide; and, the oxide semiconductor pattern may include at least one of indium-gallium oxide and indium-gallium-zinc oxide. An oxygen defect content of the oxide semiconductor pattern may be 0.14 or less compared to the total oxygen content included in the oxide semiconductor pattern.

An integrated circuit memory device according to some embodiments of the inventive concept may include a substrate, a bit line extending in a first direction parallel to an upper surface of the substrate, and oxide semiconductor patterns on the bit line. Each of the oxide semiconductor patterns includes first and second vertical portions facing each other in the first direction, buffer patterns extending on the first and second vertical portions, and word lines on the oxide semiconductor patterns. Each of the word lines includes first and second word lines extending adjacent to the first and second vertical portions, respectively, and between the first and second vertical portions. In addition, capacitors are provided, which are electrically connected to the first and second vertical portions, respectively. According to some embodiments, each of the buffer patterns includes at least one of hafnium oxide, zirconium oxide, and aluminum oxide, and each of the oxide semiconductor patterns has a mean grain size of 10 nm to 17 nm.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a cross-sectional view of a transistor including an auxiliary pattern and an oxide semiconductor pattern according to an embodiment of the inventive concept.

FIG. 2A is an enlarged view of the oxide semiconductor pattern of FIG. 1.

FIG. 2B illustrates a crystal structure of the oxide semiconductor pattern of FIG. 1 according to some embodiments of the inventive concept.

FIGS. 3A to 3C are cross-sectional views showing a manufacturing process of the transistor shown in FIG. 1.

FIG. 4A is a graph showing a mean grain size and degree of oxygen defect improvement, a mean grain size, degree of threshold voltage variation according to First and Second Examples and a Comparative Example, respectively.

FIG. 4B is a graph showing relationship between X-ray measurement angle and X-ray intensity according to Third and Fourth Examples.

FIG. 4C is a graph showing relationship between X-ray measurement angle and X-ray intensity according to Second and Third Comparative Examples.

FIG. 5 is a plan view showing a semiconductor device including a buffer pattern according to embodiments of the inventive concept.

FIG. 6 is a cross-sectional view corresponding to line A-A′ in FIG. 5.

FIGS. 7A to 7G are cross-sectional views showing a manufacturing process of a semiconductor device according to some embodiments of the inventive concept.

### DETAILED DESCRIPTION

Hereinafter, the inventive concept will be described in detail by explaining embodiments of the inventive concept with reference to the accompanying drawings.

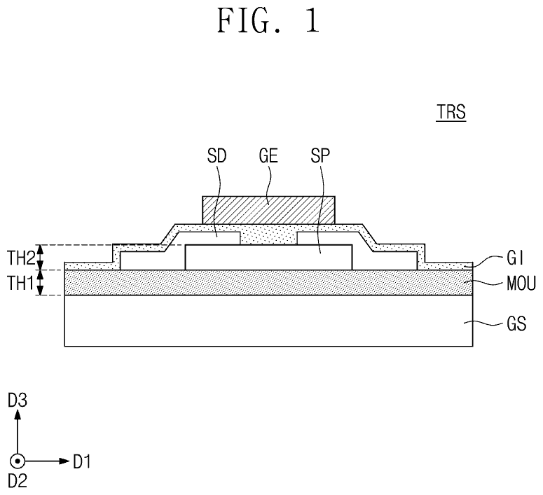

FIG. 1 is a cross-sectional view of a transistor including an auxiliary pattern and an oxide semiconductor pattern according to an embodiment of the inventive concept. Referring to FIG. 1, a base substrate GS may be provided. The base substrate GS may be a silicon substrate. Alternatively, according to some embodiments of the inventive concept, the base substrate GS may be a metal substrate, a plastic substrate, or a glass substrate.

A transistor TRS may be disposed on the base substrate GS. The transistor TRS may include a buffer substrate MOU, an oxide semiconductor pattern SP, a gate insulating pattern GI, and source/drain patterns SD. The transistor TRS may be a MOS field effect transistor.

The buffer substrate MOU may be provided on the base substrate GS. In this specification, the buffer substrate MOU and a buffer pattern MO may include substantially the same material. The buffer substrate MOU may have a first thickness TH1. For example, the first thickness TH1 may be 10 nm to 13 nm. The buffer substrate MOU may include at least one of hafnium oxide, zirconium oxide, and aluminum oxide. In this case, a concentration of hafnium, zirconium, and aluminum included in the buffer substrate MOU may be 30 at % to 40 at %. The buffer substrate MOU may include at least one of a monoclinic crystal phase and a tetragonal crystal phase. For example, a lattice constant of the buffer substrate MOU may be 4 Å to 6 Å. A surface roughness (RMS) of the buffer substrate MOU may be 0.5 nm or more.

The oxide semiconductor pattern SP may be provided on the buffer substrate MOU. The oxide semiconductor pattern SP may have a second thickness TH2. For example, the second thickness TH2 may be 8 nm to 12 nm. The oxide semiconductor pattern SP may include at least one of indium gallium oxide (IGO) and indium gallium zinc oxide (IGZO). In this case, a concentration of indium in the oxide semiconductor pattern SP may be 30 at % to 80 at %. A lattice constant of the oxide semiconductor pattern SP may be greater than the lattice constant of the buffer substrate MOU. For example, the lattice constant of the oxide semiconductor pattern SP may be 9 Å to 13 Å.

In some embodiments, the oxide semiconductor pattern SP may have a band gap energy greater than that of silicon. For example, the oxide semiconductor pattern SP may have a bandgap energy of about 1.5 eV to 5.6 eV. For example, the semiconductor pattern SP may have optimal channel performance when the semiconductor pattern SP has a bandgap energy of about 2.0 eV to 4.0 eV.

The source/drain patterns SD may be disposed to be spaced apart from each other on the buffer substrate MOU with the oxide semiconductor pattern SP interposed therebetween. The source/drain patterns SD may cover a portion of an upper surface of the oxide semiconductor pattern SP. The source/drain patterns SD may include a conductive material, for example, indium-tin oxide.

The gate insulating pattern GI may cover a portion of an upper surface of the oxide semiconductor pattern SP and the source/drain patterns SD on the buffer substrate MOU. The gate insulating pattern GI may include at least one of silicon oxide, silicon oxynitride, and a high dielectric material having a higher dielectric constant than silicon oxide.

A conductive pattern GE may be provided on the gate insulating pattern GI. The conductive pattern GE may include at least one of a metal (e.g., Al, Cu, Ti, Ta, Ru, W, Mo, Pt, Ni, Co, etc.), a conductive metal nitride (e.g., TiN, TaN, WN, NbN, TiAlN, TiSiN, TaSiN, RuTiN, etc.), a conductive metal silicide and a conductive metal oxide (e.g. PtO, RuO₂, IrO₂, SrRuO₃ (SRO), (Ba,Sr) RuO₃ (BSRO), CaRuO₃ (CRO), LSCo, etc.), but is not limited thereto. The conductive pattern GE may include a single layer or multiple layers of the materials described above.

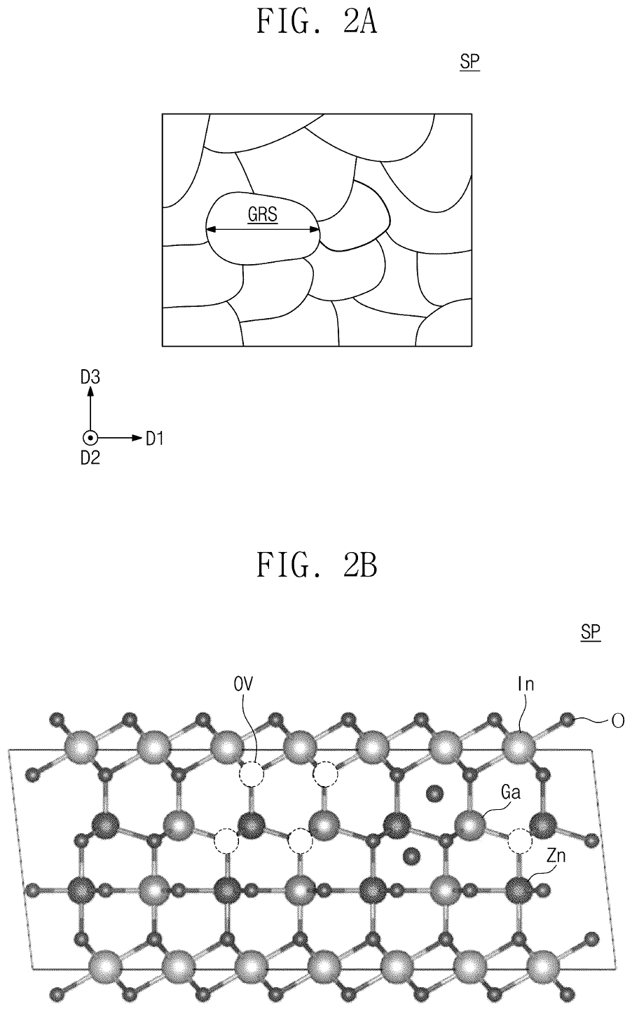

FIG. 2A is an enlarged view of the oxide semiconductor pattern SP of FIG. 1. FIG. 2B illustrates a crystal structure of the oxide semiconductor pattern of FIG. 1 according to some embodiments of the inventive concept. For example, the oxide semiconductor pattern SP of FIG. 2B may be indium-gallium-zinc oxide. Referring to FIGS. 2A and 2B, a mean grain size GRS of the oxide semiconductor pattern SP may be 10 nm to 17 nm. The oxide semiconductor pattern SP may have an oxygen vacancy OV. An oxygen defect content of the oxide semiconductor pattern SP according to an embodiment of the inventive concept may be 0.14 or less compared to the total oxygen content included in the oxide semiconductor pattern SP.

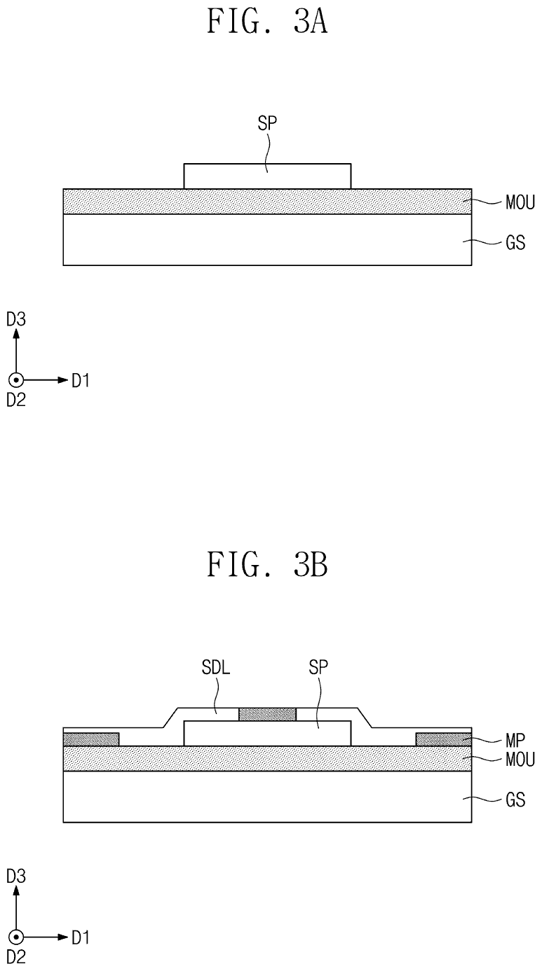

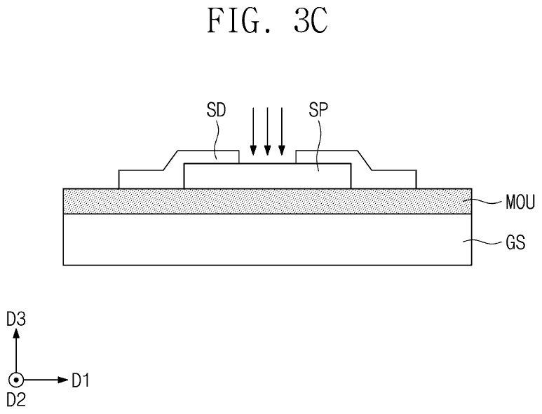

FIGS. 3A to 3C are cross-sectional views showing a manufacturing process of the transistor shown in FIG. 1. Referring to FIG. 3A, a buffer substrate MOU may be formed on the base substrate GS. Forming the buffer substrate MOU may be performed by an atomic layer deposition (ALD) process. Although FIG. 3A shows the buffer substrate MOU covering the entire upper surface of the base substrate GS, the inventive concept is not limited thereto. According to some embodiments, the buffer substrate MOU may be patterned.

An oxide semiconductor pattern SP may be formed on the buffer substrate MOU. Forming the oxide semiconductor pattern SP may include forming an oxide semiconductor layer (not shown) on the buffer substrate MOU and patterning the oxide semiconductor layer (not shown). Forming the oxide semiconductor layer (not shown) may be performed by an atomic layer deposition process. For example, a temperature at which the atomic layer deposition process is performed may be 250° C. Afterwards, a heat treatment process may be performed on the buffer substrate MOU and the oxide semiconductor pattern SP. As an example, the heat treatment process may be performed at 400° C. to 700° C.

Referring to FIG. 3B, a mask pattern MP may be formed on the buffer substrate MOU and the oxide semiconductor pattern SP. The mask pattern MP may define a region where a source/drain pattern SD will be formed. Afterwards, a source/drain layer SDL may be formed on the buffer substrate MOU. The source/drain layer SD may be formed to cover a portion of the upper surface of the oxide semiconductor pattern SP.

Referring to FIG. 3C, the mask pattern MP may be removed. Removing the mask pattern MP may be performed, for example, by a lift-off process. Due to the lift-off process, a source/drain pattern SD may be formed from the source/drain layer SDL, and a portion of the upper surface of the oxide semiconductor pattern SP may be exposed.

Ozone (O₃) may be doped into the oxide semiconductor pattern SP through an in-situ process. As the ozone is doped into the oxide semiconductor pattern SP, impurities in the oxide semiconductor pattern SP formed in the previous process may be removed. In addition, as ozone diffuses along grain boundaries of the oxide semiconductor pattern SP, degree of oxygen defects in the oxide semiconductor pattern SP may be reduced (refer to FIGS. 2A and 2B).

Thereafter, referring again to FIG. 1, a gate insulating pattern GI and a conductive pattern GE may be sequentially formed on the buffer substrate MOU, thereby completing the transistor including the buffer substrate MOU according to an embodiment of the inventive concept. In this case, forming the gate insulating pattern GI may be performed, for example, in a temperature range of 400° C. to 700° C.

### First Example

As described in FIGS. 3A to 3C, a buffer substrate MOU and an oxide semiconductor pattern SP were formed. The buffer substrate MOU included hafnium oxide. The oxide semiconductor pattern SP included indium-gallium oxide, and concentrations of indium and gallium in the oxide semiconductor pattern SP were 80 at % and 20 at %, respectively. A mean grain size GRS of the buffered oxide semiconductor pattern SP on the buffer substrate MOU was 15.37 nm.

### Second Example

In First Example, a material included in the buffer substrate MOU was changed to zirconium oxide. A mean grain size GRS of the oxide semiconductor pattern SP buffered on the buffer substrate MOU was 16.63 nm.

### First Comparative Example

In First Example, a material included in the buffer substrate MOU was changed to silicon oxide. A mean grain size GRS of the oxide semiconductor pattern SP buffered on the buffer substrate MOU was 17.82 nm.

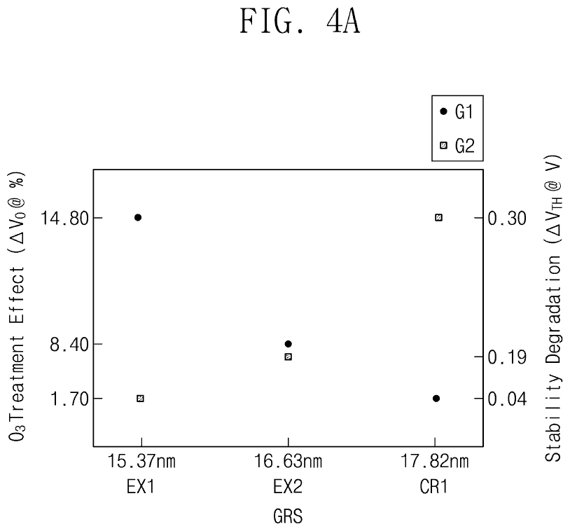

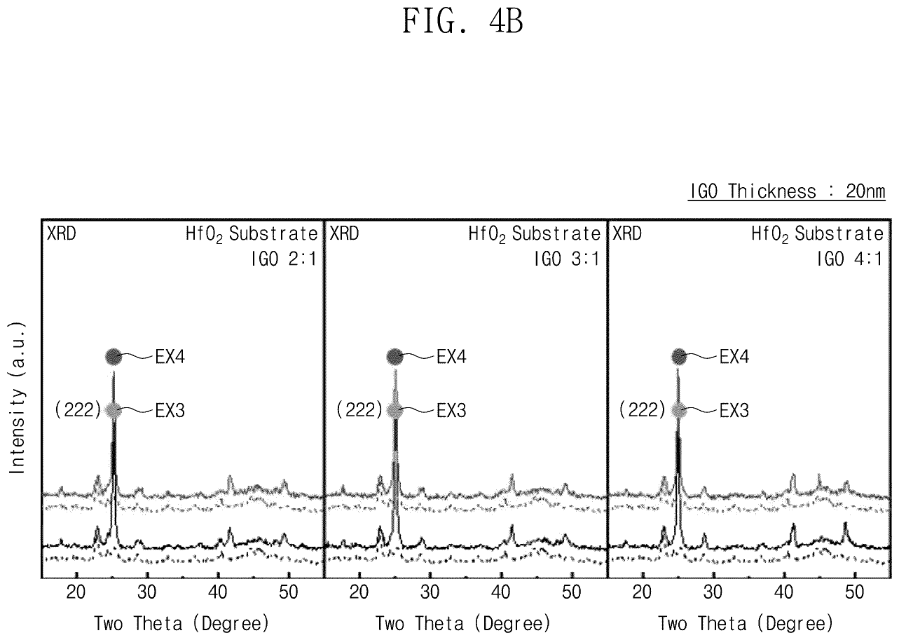

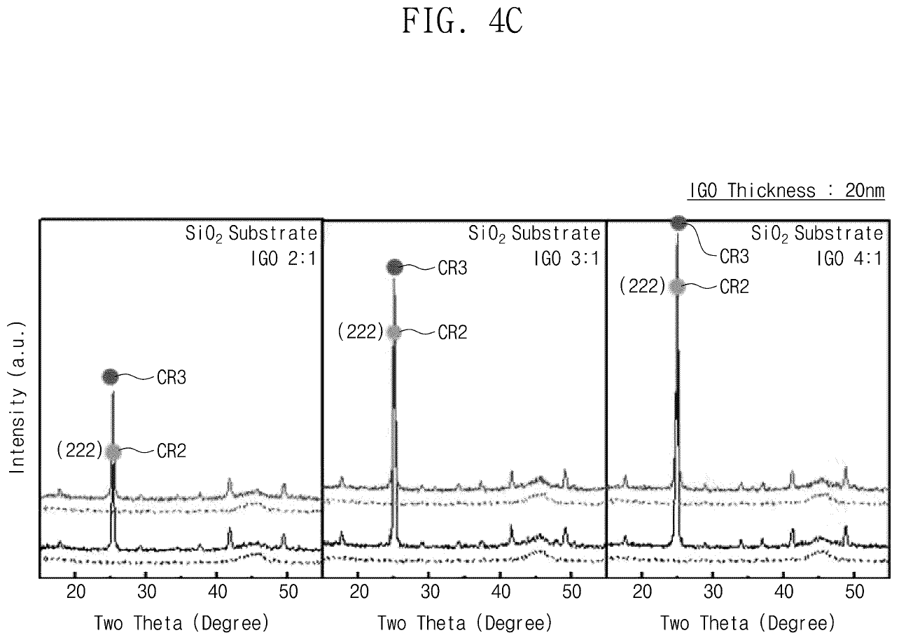

FIG. 4A is a graph showing a mean grain size and degree of oxygen defect improvement, a mean grain size, degree of threshold voltage variation according to First and Second Examples and First Comparative Example, respectively. Specifically, Graph 1 G1 shows relationship between a mean grain size GRS and degree of oxygen defects improvement due to ozone (O₃) diffusion according to First example EX1, Second example EX2, and First comparative example CR1. Graph 2 G2 shows relationship between the mean grain size GRS and degree of variation in threshold voltage according to First example EX1, Second example EX2, and First comparative example CR1.

Referring to Graph 1 G1 of FIG. 4A, the mean grain size GRS of the oxide semiconductor pattern SP of each of First example EX1 and Second example EX2 is smaller than the mean grain size GRS of the oxide semiconductor pattern SP of First comparative example CR1. Accordingly, as the oxide semiconductor pattern SP of First example EX1 and Second example EX2 has the large total area of grain boundaries, compared to the oxide semiconductor pattern SP of First comparative example CR1, ozone may diffuse well, thereby reducing degree of oxygen vacancy in the oxide semiconductor pattern SP. For example, degree of oxygen defect improvement in First example EX1, Second example EX2, and First comparative example CR1 are 14.8%, 8.4%, and 1.7%, respectively.

Referring to Graph 2 G2, variation in the threshold voltage of the oxide semiconductor pattern SP of First example EX1 and Second example EX2 is lower than variation of the oxide semiconductor pattern SP of First comparative example CR1. For example, the threshold voltage variations of First example EX1, Second example EX2, and First comparative example CR1 are 0.04 V, 0.19 V, and 0.3 V, respectively. That is, the semiconductor device to which the oxide semiconductor pattern SP of First example EX1 and Second example EX2 is applied may have a constant current value due to a low threshold voltage variation. As a result, operational reliability of the semiconductor device to which the oxide semiconductor pattern SP of First example EX1 and Second example EX2 is applied may be higher than operational reliability of the semiconductor device to which the oxide semiconductor pattern SP of the first comparative example CR1 is applied.

### Third Example

As described in FIGS. 3A to 3C, a buffer substrate MOU and an oxide semiconductor pattern SP were formed. Afterwards, a heat treatment process was performed at 400° C. on the buffer substrate MOU and oxide semiconductor pattern SP. The buffer substrate MOU included hafnium oxide. The oxide semiconductor pattern SP included indium-gallium oxide, and in this case, ratios (at %) of indium and gallium in the oxide semiconductor pattern SP were adjusted to 2:1, 3:1, and 4:1, respectively, to increase the content of indium. A thickness of the oxide semiconductor pattern SP was 20 nm.

### Fourth Example

In Fourth example, a temperature at which the heat treatment process for the buffer substrate MOU and the oxide semiconductor pattern SP is performed was changed to 700° C.

### Second Comparative Example

In the Second Comparative example, a material included in the buffer substrate MOU was changed to silicon oxide.

### Third Comparative Example

In Third comparative example, a material included in the buffer substrate MOU was changed to silicon oxide. Additionally, in the Third comparative example, a temperature at which the heat treatment process on the buffer substrate MOU and the oxide semiconductor pattern SP is performed was changed to 700° C.

FIG. 4B is a graph showing relationship between X-ray measurement angle and X-ray intensity according to Third and Fourth Examples. FIG. 4C is a graph showing relationship between X-ray measurement angle and X-ray intensity according to Second and Third Comparative Examples.

Specifically, FIG. 4B is a graph showing an X-ray measurement intensity at a (222) crystal plane of the oxide semiconductor pattern SP as a content of indium increases in Third example EX3 and Fourth example EX4. FIG. 4C is a graph showing an X-ray measurement intensity at a (222) crystal plane of the oxide semiconductor pattern SP as a content of indium increases in Second comparative example CR2 and Third comparative example CR3.

Referring to FIGS. 4B and 4C, in the case of Third example EX3 and Fourth example EX4, even when a ratio of indium increases, the amount of change in the X-ray measurement intensity for the (222) crystal plane is small. On the other hand, in the case of Second comparative example CR2 and Third comparative example CR3, as a ratio of indium increases, the X-ray measurement intensity for the (222) crystal plane increases. Additionally, in the case of Fourth example EX4, even when a temperature of the heat treatment process increases, the X-ray measurement intensity may be maintained at a lower measurement intensity compared to Third comparative example CR3.

That is, in the case of Third example EX3 and Fourth example EX4, it may be seen that a crystal growth rate of the oxide semiconductor pattern SP is slow even when the temperature and the indium content increase, whereas, in the case of Second comparative example CR2 and Third comparative example CR3, it may be seen that a crystal growth rate of the oxide semiconductor pattern SP is fast as the temperature and the indium content increase.

The semiconductor device according to an embodiment of the inventive concept may include the buffer pattern and the oxide semiconductor pattern formed on the buffer pattern. For example, the buffer pattern may include at least one of hafnium oxide, zirconium oxide, and aluminum oxide. In this case, the surface roughness of the buffer pattern is 0.5 nm or more, and the lattice constant of the buffer pattern may be smaller than the lattice constant of the oxide semiconductor pattern. As a result, when forming the oxide semiconductor pattern on the buffer pattern, the crystal growth rate of the oxide semiconductor pattern slows down, and as the mean grain size decreases, the total area of the grain boundary may increase. In particular, when manufacturing the semiconductor device, a grain growth of the oxide semiconductor pattern may be suppressed even when the process is performed at a high temperature.

Accordingly, in the ozone injection process for the oxide semiconductor pattern, ozone diffuses easily into the oxide semiconductor pattern through grain boundaries, and thus the degree of oxygen defects present in the oxide semiconductor pattern may be reduced. As the degree of oxygen defects decreases, charge trapping phenomenon of carriers moving in the oxide semiconductor pattern may be reduced, thereby improving electrical characteristics and reliability of the semiconductor device.

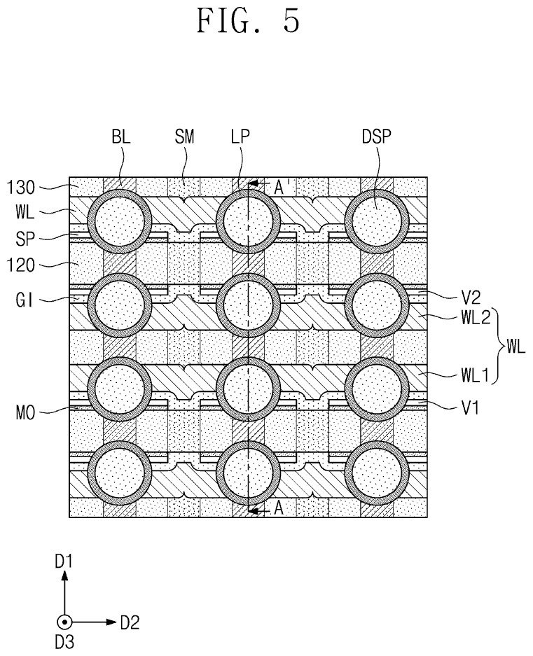

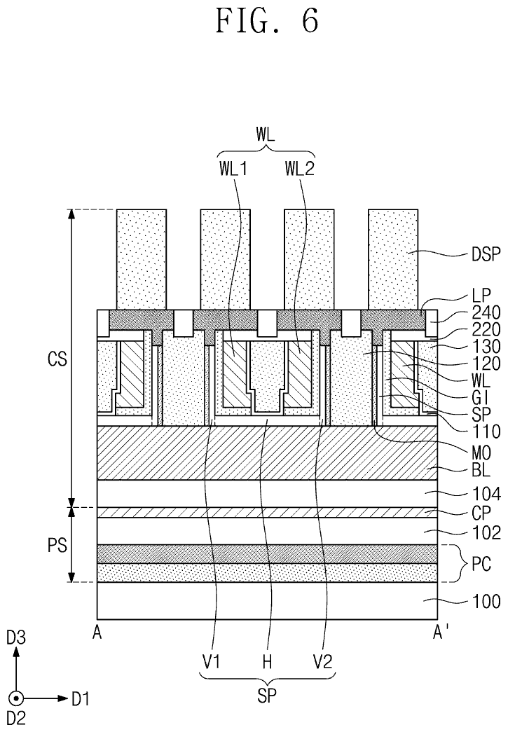

FIG. 5 is a plan view showing a semiconductor device including a buffer pattern according to embodiments of the inventive concept. FIG. 6 is a cross-sectional view corresponding to line A-A′ in FIG. 5. Referring to FIGS. 5 and 6, a semiconductor device may include a substrate 100, a peripheral circuit structure PS on the substrate 100, and a cell array structure CS on the peripheral circuit structure PS.

The substrate 100 may be a semiconductor substrate, such as a silicon substrate, a germanium substrate, or a silicon-germanium substrate, for example. The peripheral circuit structure PS may include a peripheral gate structure PC integrated on the substrate 100, peripheral contact pads CP, peripheral contact plugs (not shown), and a first interlayer insulating layer 102 covering the peripheral gate structure. The peripheral gate structure PC may include circuitry such as a sense amplifier.

The cell array structure CS may include memory cells including vertical channel transistors. The cell array structure CS may include a plurality of cell contact plugs (not shown), a plurality of bit lines BL, a plurality of shielding structures SM, a second interlayer insulating layer 104, a plurality of buffer patterns MO, a plurality of oxide semiconductor patterns SP, a plurality of word lines WL, a gate insulating pattern GI, and capacitors DSP. The word line WL described in FIGS. 5 and 6 may correspond to the conductive pattern GE described in FIG. 1. The buffer pattern MO described in FIGS. 5 and 6 may include substantially the same material as the buffer substrate MOU described in FIG. 1.

Each of the first and second interlayer insulating layers 102 and 104 may include multi-layered insulating layers and, for example, may include at least one of silicon oxide, silicon nitride, silicon oxynitride, and a low dielectric material. The bit line BL may be provided on the substrate 100 and may extend in a first direction D1. A plurality of bit lines BL may be provided, and the bit lines BL may be spaced apart from each other in a second direction D2. The bit line BL may be electrically connected to the peripheral contact pad CP through a cell contact plug.

In this specification, the first direction D1 is defined as a direction parallel to an upper surface of the substrate 100. The second direction D2 is parallel to the upper surface of the substrate 100 and is defined as a direction perpendicular to the first direction D1. A third direction D3 is defined as a direction perpendicular to the upper surface of the substrate 100.

The bit line BL may include at least one of, for example, doped polysilicon, a metal (e.g., Al, Cu, Ti, Ta, Ru, W, Mo, Pt, Ni, Co), a conductive metal nitride (e.g., TiN, TaN, WN, NbN, TiAlN, TiSiN, TaSiN, RuTiN), a conductive metal silicide and a conductive metal oxide (e.g., PtO, RuO₂, IrO₂, SrRuO₃ (SRO), (Ba,Sr) RuO₃ (BSRO), CaRuO₃ (CRO), LSCo), but is not limited thereto. The bit line BL may include a single layer or multiple layers of the above-described materials. In some embodiments, the bit line BL may include a two-dimensional semiconductor material, and for example, the two-dimensional material may include at least one of graphene and carbon nanotubes.

The shielding structures SM may be provided between the bit lines BL, respectively, and the shielding structures SM may extend in the first direction D1. The shielding structures SM may include, for example, a conductive material such as metal. The shielding structures SM may be provided in the second interlayer insulating layer 104.

The buffer pattern MO may be provided on the bit line BL. A lower surface of the buffer pattern MO may be in contact with an upper surface of the bit line BL. The buffer pattern MO may include at least one of hafnium oxide, zirconium oxide, and aluminum oxide. The buffer pattern MO may include at least one of a monoclinic crystal phase and a tetragonal crystal phase. A lattice constant of the buffer pattern MO may be 4 Å to 6 Å. A surface roughness (RMS) of the buffer pattern may be 0.5 nm or more. For example, a thickness of the buffer pattern MO may be 10 nm to 13 nm.

An oxide semiconductor pattern SP may be disposed on the bit line BL. A plurality of oxide semiconductor patterns SP may be provided. Each of the oxide semiconductor patterns SP may be spaced apart from each other in the first and second directions D1 and D2.

The oxide semiconductor pattern SP may include a first vertical portion V1 and a second vertical portion V2 that face each other. The oxide semiconductor pattern SP may further include a horizontal portion H connecting the first and second vertical portions V1 and V2. The horizontal portion H may be adjacent to a lower portion of each of the first and second vertical portions V1 and V2 and connect the first and second vertical portions V1 and V2. In this case, the above-described buffer pattern MO may be provided on the first and second vertical portions V1 and V2 of the oxide semiconductor pattern SP. A level of an upper surface of the buffer pattern MO may be substantially the same as a level of an upper surfaces of the first and second vertical portions V1 and V2. A level of a lower surface of the buffer pattern MO may be substantially the same as a level of a lower surface of the horizontal portion H.

The horizontal portion H of the oxide semiconductor pattern SP may include a common source/drain region, and upper portions of the first and second vertical portions V1 and V2 may include first and second source/drain regions, respectively. The first vertical portion V1 may include a first channel region between a common source/drain region and a first source/drain region, and the second vertical portion V2 may include a common source/drain region and a second source/drain region. Each of the first and second vertical portions V1 and V2 may be electrically connected to the bit line BL. That is, the semiconductor device according to the inventive concept may have a structure in which a pair of vertical channel transistors share one bit line BL.

The oxide semiconductor pattern SP may include at least one of indium-gallium oxide and indium-gallium-zinc oxide. In this case, a concentration of indium in the oxide semiconductor pattern SP may be 30 at % to 80 at %. A mean grain size of the oxide semiconductor pattern SP may be 10 nm to 17 nm (refer to FIGS. 2A and 2B). An oxygen defect content of the oxide semiconductor pattern SP may be 0.14 or less compared to the total oxygen content included in the oxide semiconductor pattern SP. A lattice constant of the oxide semiconductor pattern SP may be 9 Å to 13 Å. For example, a thickness of the oxide semiconductor pattern SP may be 8 nm to 12 nm.

The word line WL may be disposed between the first vertical portion V1 and the second vertical portion V2. A plurality of word lines WL may be provided. The word lines WL may extend in the second direction D2 and be spaced apart from each other in the first direction D1.

Each of the word lines WL may include a first word line WL1 and a second word line WL2, and the first word line WL1 and the second word line WL2 may face each other in in the first direction D1. The first word line WL1 may cover an inner surface of the first vertical portion V1, and the inner surface of the first vertical portion V1 may be one side of the first vertical portion V1 facing the second vertical portion V2.

The first word line WL1 may be adjacent to the first channel region of the first vertical portion V1 and may control the first channel region. The second word line WL2 may cover an inner surface of the second vertical portion V2, and the inner surface of the second vertical portion V2 may be one side of the second vertical portion V2 facing the first vertical portion V1. The second word line WL2 may be adjacent to the second channel region of the second vertical portion V2 and may control the second channel region.

The gate insulating pattern GI may be interposed between the oxide semiconductor pattern SP and the word line WL. In detail, the gate insulating pattern GI may be interposed between an inner surface of the first vertical portion V1 and the first word line WL1, and between an inner surface of the second vertical portion V2 and the second word line WL2. The gate insulating pattern GI may further extend between the horizontal portion H and the word line WL. The word line WL may be separated from the semiconductor pattern SP by the gate insulating pattern GI. The gate insulating pattern GI may be disposed to be spaced apart from the buffer pattern MO.

A first insulating pattern 120 may be interposed between adjacent semiconductor patterns SP in the first direction D1. A plurality of first insulating patterns 120 may be provided. The first insulating patterns 120 may extend in the second direction D2 across the bit line BL and may be spaced apart from each other in the first direction D1. In this case, the above-described buffer pattern MO may be disposed on a side surface of the first insulating pattern 120. That is, the buffer pattern MO may be interposed between the first and second vertical portions V1 and V2 and the first insulating pattern 120. The first insulating pattern 120 may include at least one of silicon oxide, silicon nitride, silicon oxynitride, and a low dielectric material. As an example, the first insulating pattern 120 may be formed of a single layer or multiple layers.

A second insulating pattern 130 may be disposed between the first word line WL1 and the second word line WL2 of the word line WL. A plurality of second insulating patterns 130 may be provided. The second insulating patterns 130 may extend in the second direction D2 across the bit line BL and may be spaced apart from each other in the first direction D1. The first and second insulating patterns 120 and 130 may be alternately arranged in the first direction D1. The second insulating pattern 130 may include, for example, at least one of silicon oxide, silicon nitride, silicon oxynitride, and a low dielectric material.

A capping pattern 110 may be interposed between the word line WL and the second insulating pattern 130. The capping pattern 110 may cover an inner surface of the word line WL. For example, the capping pattern 110 may include at least one of silicon oxide, silicon nitride, and silicon oxynitride.

A filling pattern 220 may be provided on an upper surface of the word line WL. The filling pattern 220 may cover upper surfaces of the capping pattern 110 and the second insulating pattern 130. The filling pattern 220 may extend in the second direction D2. For example, the filling pattern 220 may include at least one of silicon oxide, silicon nitride, and silicon oxynitride.

Landing pads LP may be provided on the first and second vertical portions V1 and V2 of the semiconductor pattern SP and the buffer pattern MO, respectively. The landing pads LP may be in direct contact with and be electrically connected to the first and second vertical portions V1 and V2 and the buffer pattern MO. When viewed in a plan view, the landing pads LP may be spaced apart from each other in the first and second directions D1 and D2 and may be arranged in various shapes such as a matrix shape, a zigzag shape, or a honeycomb shape. When viewed in a two-dimensional perspective view, each of the landing pads LP may have various shapes, such as circular, oval, rectangular, square, diamond, or hexagonal shapes.

The landing pads LP may be formed of, for example, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but is not limited thereto.

A third interlayer insulating layer 240 may fill a space between the landing pads LP on the first and second insulating patterns 120 and 130. For example, the third interlayer insulating layer 240 may include at least one of silicon oxide, silicon nitride, and silicon oxynitride, and may include a single layer or multiple layers.

The capacitors DSP may be provided on each of the landing pads LP. The capacitors DSP may be electrically connected to the first and second vertical portions V1 and V2 of the oxide semiconductor pattern SP through the landing pads LP, respectively.

The capacitors DSP may include lower and upper electrodes, and a capacitor dielectric layer interposed therebetween. In this case, the lower electrode may be in contact with the landing pad LP, and the lower electrode may have various shapes, such as circular, oval, rectangular, square, diamond, or hexagon, when viewed in a planar perspective view.

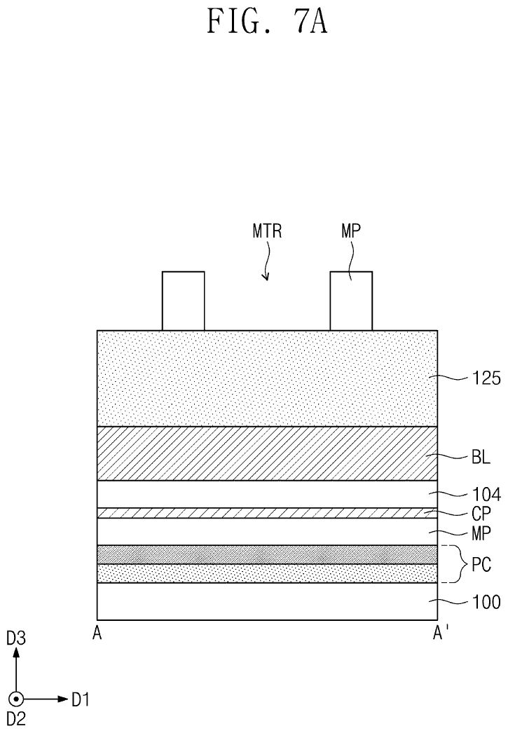

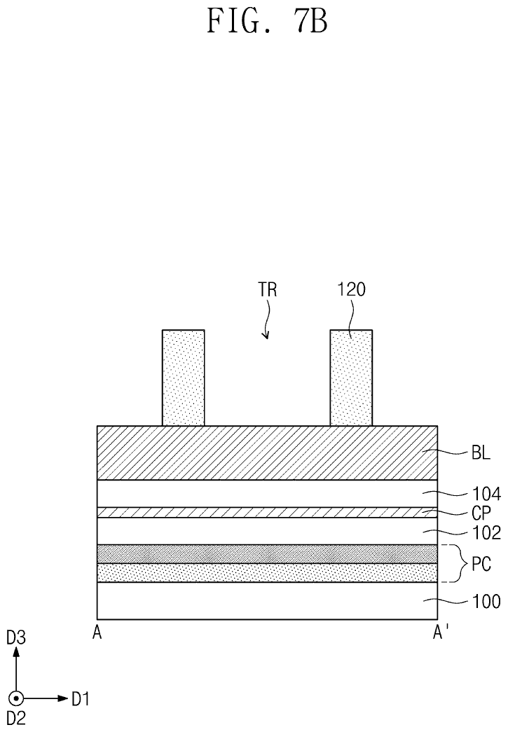

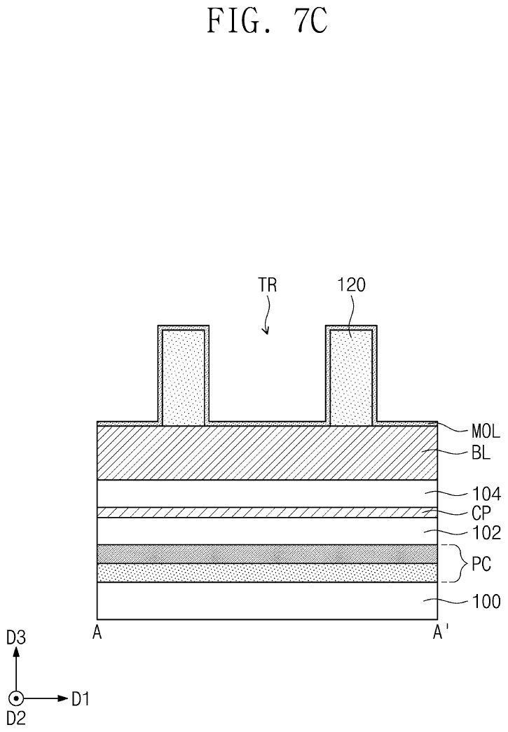

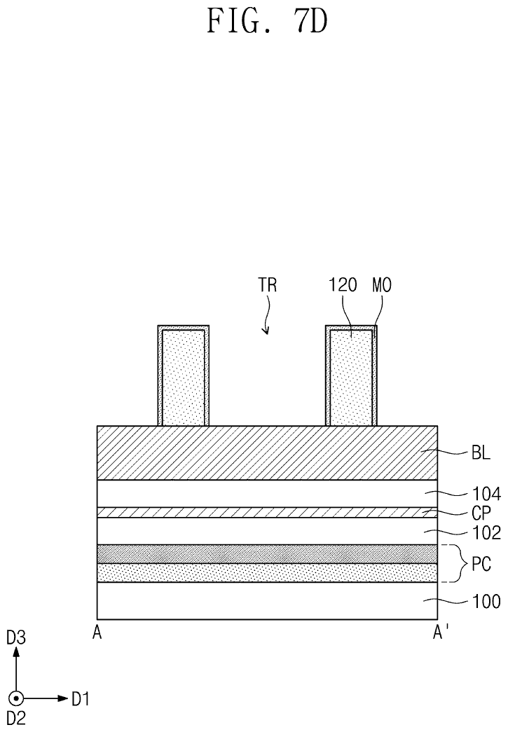

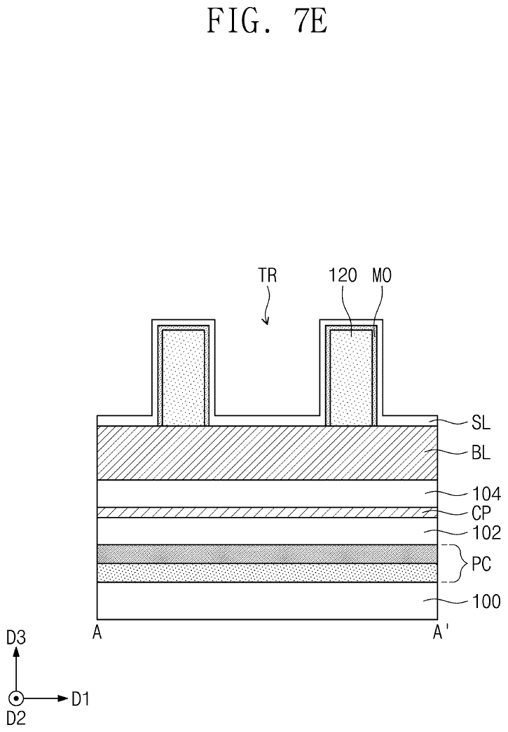

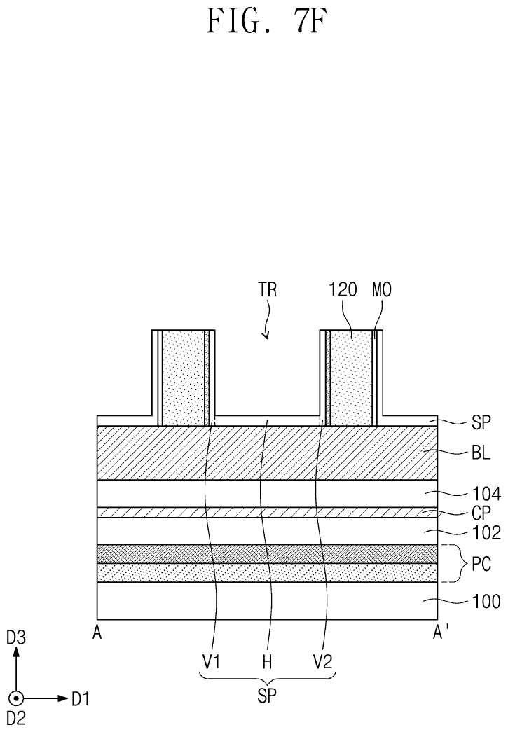

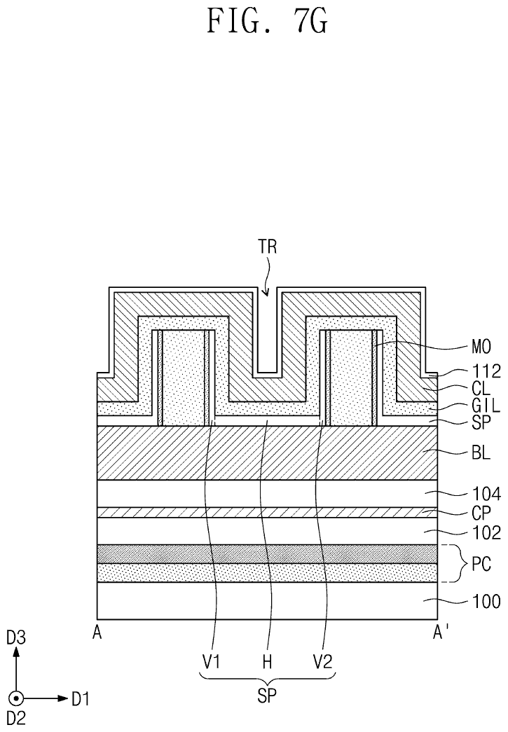

FIGS. 7A to 7G are cross-sectional views showing a manufacturing process of a semiconductor device according to some embodiments of the inventive concept. Specifically, FIGS. 7A to 7G are cross-sectional views corresponding to line A-A′ in FIG. 5. Referring to FIG. 7A, a bit line BL may be formed on the substrate 100. A plurality of bit lines BL may be provided. The bit lines BL may extend in the first direction D1 and be spaced apart from each other in the second direction D2. The bit line BL may be formed to be electrically connected to lower wiring. Forming the bit line BL may include depositing a bit line layer (not shown) on the substrate 100 and patterning the bit line layer to form the bit line BL.

A first insulating layer 125 and mask patterns MP may be sequentially formed on the bit line BL. The first insulating layer 125 may cover the entire upper surface of the substrate 100. For example, the first insulating layer 125 may include at least one of silicon oxide, silicon nitride, silicon oxynitride, and a low dielectric material.

Mask patterns MP may include line patterns that extend in the second direction D2 and are spaced apart from each other in the first direction D1. The mask patterns MP may have a mask trench MTR, and a plurality of mask trenches MTR may be provided. The mask trenches MTR may be spaced apart from each other in the first direction D1 and may extend in the second direction D2.

Referring to FIG. 7B, a plurality of first insulating patterns 120 may be formed on the bit line BL. Forming the first insulating pattern 120 may include etching the first insulating layer 125 using the mask patterns MP of FIG. 7A as an etch mask. The first insulating pattern 120 may extend in the second direction D2. The first insulating pattern 120 may have a trench region TR. A plurality trench regions TR may be provided and may extend in the second direction D2.

Referring to FIG. 7C, a buffer layer MOL may be formed to cover an upper surface of the bit line BL and side and upper surfaces of the first insulating pattern 120. The buffer layer MOL may conformally cover the upper surface of the bit line BL and the first insulating pattern 120. For example, forming the buffer layer MOL may be performed through an atomic layer deposition process.

Referring to FIG. 7D, a portion of the buffer layer MOL may be removed. Removing the portion of the buffer layer MOL may include removing the buffer layer MOL on the upper surface of the bit line BL. Removing the portion of the buffer layer MOL may be performed through an anisotropic etching process. As a result, a plurality of buffer patterns MO may be formed from the buffer layer MOL.

Referring to FIG. 7E, an oxide semiconductor layer SL may be formed to cover the upper surface of the bit line BL and the side and upper surfaces of the buffer pattern MO. Forming the oxide semiconductor layer SL may be performed using at least one of a physical vapor deposition process, a chemical vapor deposition process, a plasma enhanced chemical vapor deposition process, and an atomic layer deposition process.

Referring to FIG. 7F, a portion of the semiconductor layer SL may be removed. Removing the portion of the semiconductor layer SL may include removing the semiconductor layer SL on an upper surface of the first insulating pattern 120. As a result, a plurality of oxide semiconductor patterns SP may be formed from the semiconductor layer SL. Each of the oxide semiconductor patterns SP may include a first vertical portion V1 and a second vertical portion V2 facing each other, and a horizontal portion H connecting the first and second vertical portions V1 and V2. Referring to FIG. 7G, a gate insulating layer GIL, a conductive layer CL, and an additional layer 112 may be formed to cover the substrate 100. The gate insulating layer GIL, the conductive layer CL, and the additional layer 112 may conformally cover inner surfaces of the first and second vertical portions V1 and V2, an upper surface of the horizontal portion H, and an upper surface of the first insulating pattern 120, and may fill a portion of the trench region TR. Forming the gate insulating layer GIL, the conductive layer CL, and the additional layer 112 may include sequentially depositing the gate insulating layer GIL, the conductive layer CL, and the additional layer 112 using at least one of a physical vapor deposition process, a chemical vapor deposition process, a plasma enhanced chemical vapor deposition process, and an atomic layer deposition process.

Referring again to FIG. 6, a word line WL and a gate insulating pattern GI may be formed. The word line WL may be formed to include a first word line WL1 on the first vertical portion V1 and a second word line WL2 on the second vertical portion V2. Forming the word line WL may include, for example, removing the conductive layer CL on the first insulating pattern 120 and the horizontal portion H to separate the conductive layer CL into a plurality of word lines WL. When forming the word line WL, the gate insulating layer GIL on the first insulating pattern 120 and the horizontal portion H may be removed and separated into a plurality of gate insulating patterns GI.

A portion of the additional layer 112 may be removed in the removal process. After the removal process, a dummy additional layer (not shown) may be formed on the remainder of the additional layer 112, and the remainder of the additional layer 112 and the dummy additional layer (not shown) may form a capping pattern 110. Thereafter, a second insulating pattern 130 may be formed between the first word line WL1 and the second word line WL2. The second insulating pattern 130 may fill the trench region TR. Forming the second insulating pattern 130 may include filling the trench region TR and forming a second insulating layer (not shown) covering the oxide semiconductor pattern SP, the buffer pattern MO, the gate insulating pattern GI, and word line WL, and removing an upper portion of the second insulating layer to separate the second insulating layer into a plurality of second insulating patterns 130. An upper surface of the second insulating pattern 130 may be formed to be positioned at a lower height than an upper surface of the gate insulating pattern GI and an upper surface of the first insulating pattern 120, and may be formed to be positioned at a height adjacent to the upper surface of the word line WL.

A filling pattern 220 may be formed on the word line WL. Forming the filling pattern 220 includes forming a filling layer (not shown) that covers the upper surface of the word line WL and the second insulating pattern 130, and removing an upper portion of the filling layer to separate the filling layer into a plurality of filling patterns 220.

Landing pads LP may be formed on the first and second vertical portions V1 and V2 of the semiconductor pattern SP, respectively. Forming the landing pads LP may include removing upper portions of the buffer pattern MO and the first and second vertical portions V1 and V2 to form a recessed region, filling the recessed region to form a landing pad layer (not shown) covering the filling pattern 220, and partially removing the landing pad layer and separating the landing pad layer into a plurality of landing pads.

A third interlayer insulating layer 240 may be formed to fill a space between the landing pads LP on the first and second insulating patterns 120 and 130. Capacitors DSP may be formed on the landing pads LP, respectively. The capacitors DSP may be electrically connected to the first and second vertical portions V1 and V2 of the semiconductor pattern SP through the landing pads LP, respectively.

The oxide semiconductor pattern of the semiconductor device according to the inventive concept may be formed on the substrate containing hafnium oxide, zirconium oxide, or aluminum oxide. Due to the difference in lattice constant between the hafnium oxide, zirconium oxide, or aluminum oxide and the oxide semiconductor pattern, the crystal growth rate of the oxide semiconductor pattern may be reduced. As a result, the mean grain size of the oxide semiconductor pattern may decrease, thereby increasing the total area of the grain boundary. Accordingly, when ozone is doped into the oxide semiconductor pattern, the diffusion of ozone along the grain boundary may become active, thereby reducing the degree of oxygen defects in the oxide semiconductor pattern. As a result, the electrical characteristics and reliability of semiconductor devices may be improved.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A semiconductor device, comprising:
a buffer pattern having a conductive pattern thereon, said buffer pattern comprising at least one of hafnium oxide, zirconium oxide, and aluminum oxide; and
an oxide semiconductor pattern extending between the buffer pattern and the conductive pattern, said oxide semiconductor pattern having a mean grain size in a range from 10 nm to 17 nm.

2. The device of claim 1, wherein the oxide semiconductor pattern comprises a material selected from a group consisting of indium-gallium oxide and indium-gallium-zinc oxide.

3. The device of claim 1, wherein said buffer pattern has a surface roughness of 0.5 nm or greater.

4. The device of claim 1, wherein a total concentration of hafnium, zirconium, and/or aluminum in the buffer pattern is in a range from 30 at % to 40 at %.

5. The device of claim 1, wherein a lattice constant of the buffer pattern is less than a lattice constant of the oxide semiconductor pattern.

6. The device of claim 5, wherein the lattice constant of the buffer pattern is in a range from 4 Å to 6 A, and the lattice constant of the oxide semiconductor pattern is in a range from 9 Å to 13 Å.

7. A semiconductor device, comprising:
a buffer pattern including a material selected from a group consisting of hafnium oxide, zirconium oxide and aluminum oxide;
an oxide semiconductor pattern on the buffer pattern, said oxide pattern including a material selected from a group consisting of indium-gallium oxide and indium-gallium-zinc oxide, and having an oxygen defect content therein of 0.14 or less relative to a total oxygen content therein; and
an electrically conductive pattern on the oxide semiconductor pattern.

8. The device of claim 7, wherein a concentration of indium included in the oxide semiconductor pattern is in a range from 30 at % to 80 at %.

9. The device of claim 7, wherein the buffer pattern includes at least one of a monoclinic crystal phase and a tetragonal crystal phase.

10. The device of claim 7, wherein the buffer pattern has a surface roughness of 0.5 nm or greater.

11. An integrated circuit memory device, comprising:
a substrate;
a bit line extending in a first direction parallel to an upper surface of the substrate;
a plurality of oxide semiconductor patterns on the bit line, with each of the plurality of oxide semiconductor patterns including first and second vertical portions facing each other in the first direction;
a plurality of buffer patterns extending on the first and second vertical portions;
a plurality of word lines on the oxide semiconductor patterns, with each of the plurality of word lines including first and second word lines extending adjacent to the first and second vertical portions, respectively, between the first and second vertical portions; and
a plurality of capacitors electrically connected to the first and second vertical portions, respectively;
wherein each of the plurality of buffer patterns comprises a material selected from a group consisting of hafnium oxide, zirconium oxide, and aluminum oxide; and
wherein each of the plurality of oxide semiconductor patterns has a mean grain size of 10 nm to 17 nm.

12. The device of claim 11, wherein a thickness of the buffer pattern is 10 nm to 13 nm; and wherein each of the oxide semiconductor patterns has a thickness of 8 nm to 12 nm.

13. The device of claim 11, further comprising:
a gate insulating pattern extending between a corresponding one of the plurality of oxide semiconductor patterns and a corresponding one of the plurality of word lines; and
wherein each of the plurality of buffer patterns is spaced apart from the gate insulating pattern.

14. The device of claim 11, further comprising:
a landing pad on the first and second vertical portions; and
wherein each of the plurality of buffer patterns is in contact with the landing pad.

15. The device of claim 11, wherein levels of upper surfaces of the plurality of buffer patterns are substantially the same as levels of upper surfaces of the first and second vertical portions.

16. The device of claim 11,
wherein each of the plurality of oxide semiconductor patterns further includes a horizontal portion connecting the first and second vertical portions; and
wherein a level of a lower surface of the plurality of buffer patterns is substantially the same as a level of a lower surface of a corresponding one of the horizontal portions.

17. The device of claim 11, further comprising:
an insulating pattern interposed between the plurality of oxide semiconductor patterns on the bit line; and
wherein each of the plurality of buffer patterns extends on a side surface of the insulating pattern.

18. The device of claim 17, wherein each of the plurality of buffer patterns extends between the first and second vertical portions and the insulating pattern.

19. The device of claim 11, wherein an upper surface of the bit line is in contact with a lower surface of a corresponding one of the plurality of buffer patterns.

20. The device of claim 11, wherein a lattice constant of each of the plurality of buffer patterns is in a range from 4 Å to 6 Å; and wherein each of the plurality of oxide semiconductor patterns has a lattice constant in a range from 9 Å to 13 Å.
